(19) United States
(12) Patent Application Publication
(10) Pub. No.: US 2025/0313945 A1
(43) Pub. Date: Oct. 9, 2025

(54) CARRIER FOR HOLDING A SUBSTRATE, APPARATUS FOR DEPOSITING A LAYER ON A SUBSTRATE, AND METHOD FOR SUPPORTING A SUBSTRATE

(71) Applicant: Applied Materials, Inc., Santa Clara, CA (US)

(72) Inventor: Ralph LINDENBERG, Büdingen-Rinderbügen (DE)

(21) Appl. No.: 18/864,645

(22) PCT Filed: May 17, 2022
(86) PCT No.: PCT/EP2022/063287

§ 371 Date: Nov. 11, 2024

(51) Int. Cl. C23C 14/50; C23C 14/24

(52) U.S. Cl. CPC C23C 14/50; C23C 14/24

(57) ABSTRACT

A carrier for holding a substrate in a curved state is provided. The carrier comprises a carrier body having a curved substrate support surface, a sealing for providing a sealing between an edge of the substrate and the carrier body, and a substrate fixation for pressing the edge of the substrate onto the sealing. The carrier body comprises one or more gas supply conduits to provide a gas cushion between a back side of the substrate and the curved substrate support surface. Further, an apparatus for depositing a layer on a substrate in a curved state and a method for supporting a substrate in a curved state in a vacuum deposition chamber are provided.

### FIELD OF INVENTION

Embodiments of the present disclosure relate to carriers for holding a substrate, apparatuses for depositing a layer on a substrate, and methods for supporting a substrate. Embodiments of the present disclosure particularly relate to carriers for holding a substrate in a vacuum environment, deposition apparatuses including a vacuum deposition chamber, and methods for supporting a substrate in a vacuum deposition chamber.

### BACKGROUND

Techniques for layer deposition on a substrate include, for example, thermal evaporation, chemical vapor deposition (CVD) and physical vapor deposition (PVD) such as sputtering deposition. A sputter deposition process can be used to deposit a material layer on the substrate, such as a layer of an insulating material or a metal layer. During the sputter deposition process, a target having a target material to be deposited on the substrate is bombarded with ions generated in a plasma region to dislodge atoms of the target material from a surface of the target. The dislodged atoms can form the material layer on the substrate. In a reactive sputter deposition process, the dislodged atoms can react with a gas in the plasma region, for example, nitrogen or oxygen, to form an oxide, a nitride or an oxinitride of the target material on the substrate.

Coated materials can be used in several applications and in several technical fields. For instance, coated materials may be used in the field of microelectronics, such as for generating semiconductor devices. Also, substrates for displays can be coated using a PVD process. Further applications include insulating panels, organic light emitting diode (OLED) panels, substrates with thin film transistors (TFTs), color filters or the like.

During deposition, the substrates are typically exposed to elevated temperatures under vacuum conditions which poses challenges with respect to substrate handling and substrate cooling, particularly of large area thin substrates.

In light of the foregoing, there is a need to provide carriers for holding a substrate, deposition apparatuses for depositing material on a substrate, and methods for supporting a substrate that overcome at least some of the problems in the art.

### SUMMARY

In light of the above, a carrier for holding a substrate in a curved state, an apparatus for depositing a layer on a substrate in a curved state, and a method for supporting a substrate in a curved state according to the independent claims are provided. Further features, details, aspects, implementation and embodiments are shown in the dependent claims, the description and the drawings.

According to embodiments, a carrier for holding a substrate in a curved state is provided. The carrier includes a carrier body having a curved substrate support surface. Additionally, the carrier includes a sealing for providing a sealing between an edge of the substrate and the carrier body. Further, the carrier includes a substrate fixation for pressing the edge of the substrate onto the sealing. The carrier body includes one or more gas supply conduits to provide a gas cushion between a back side of the substrate and the curved substrate support surface.

According to embodiments, an apparatus for depositing a layer on a substrate in a curved state is provided. The apparatus includes a vacuum deposition chamber, an arrangement of deposition sources, and a carrier for holding the substrate in a curved state according to any embodiments described herein.

According to embodiments, a method for supporting a substrate in a curved state in a vacuum deposition chamber is provided. The method includes providing a carrier according to any embodiments described herein. Further, the method includes providing a gas cushion between a back side of the substrate and the curved substrate support surface.

Embodiments are also directed at apparatuses for carrying out the disclosed methods and include apparatus parts for performing each described method aspect. The method may be performed by way of hardware components, a computer programmed by appropriate software, by any combination of the two or in any other manner. Furthermore, embodiments according to the present disclosure are also directed at methods for operating the described apparatus. It includes method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic top view of a carrier according to embodiments described herein;

FIG. 2 shows a schematic front view of a carrier according to embodiments described herein;

FIGS. 3 to 6 show schematic top views of carriers according further embodiments described herein;

FIGS. 7 and 8 show schematic top views of deposition apparatuses according to embodiments described herein; and

FIG. 9 shows a block diagram for illustrating a method for supporting a substrate in a curved state according to embodiments described herein.

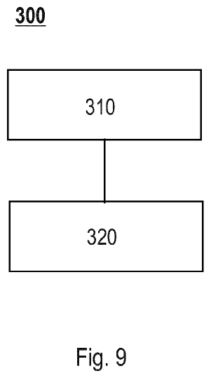

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Within the following description of the drawings, the same reference numbers refer to the same or similar components. Generally, only the differences with respect to the individual embodiments are described. Unless specified otherwise, the description of a part or aspect in one applies to a corresponding part or aspect in another embodiment as well.

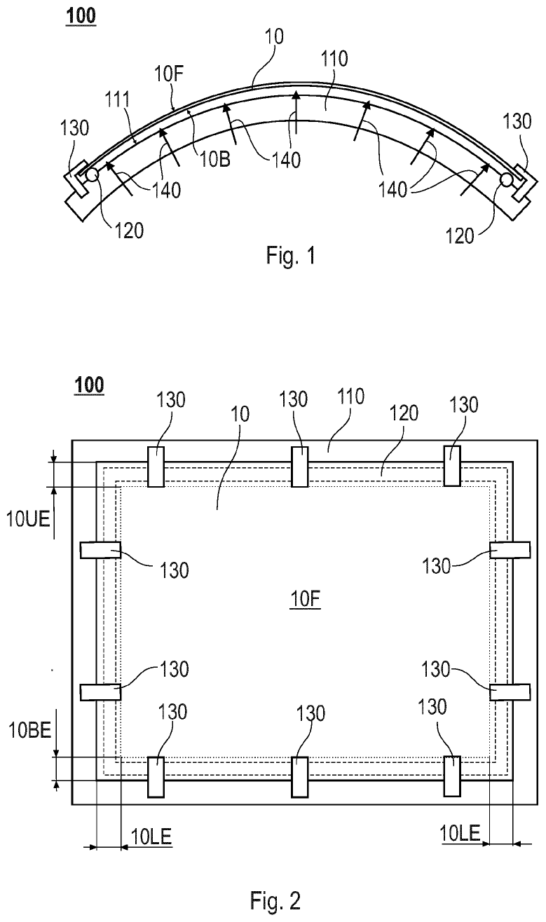

With reference to FIG. 1, a carrier 100 for holding a substrate 10 in a curved state according to the present disclosure is described. According to embodiments, which can be combined with any other embodiments described herein, the carrier 100 includes a carrier body 110 having a curved substrate support surface 111. Additionally, the carrier 100 includes a sealing 120 for providing a sealing between an edge of the substrate 10 and the carrier body 110. Further, the carrier 100 includes a substrate fixation 130 for pressing the edge of the substrate 10 onto the sealing 120. The carrier body 110 includes one or more gas supply conduits 140 to provide a gas to a back side 10B of the substrate 10, particularly to provide a gas cushion between a back side 10B of the substrate 10 and the curved substrate support surface 111.

Accordingly, compared to the prior art, an improved carrier for holding a substrate is provided. In particular, by providing a carrier which is configured to hold a substrate in a curved state, the holding stability of the substrate can be improved due to mechanical tensions in the substrate caused by the curved state of the substrate. Further, embodiments of the carrier as described herein beneficially provide for improved thermal conductance performance from the substrate to the carrier, such that cooling efficiency of the substrate can be improved. Further, it is to be noted that the carrier according to embodiments described herein is particularly well suited for cooling thin substrates, particularly large area substrates, having a thickness of 0.1 mm to 1.8 mm. In other words, compared to the state of the art, the carrier as described herein beneficially provides for a reduction of possible substrate damage. Additionally, the alignment of the substrate with respect to the susceptor, i.e. the carrier, particularly the carrier body, can be improved.

Before various embodiments of the present disclosure are described in more detail, some aspects with respect to some terms used herein are explained.

In the present disclosure, a “carrier for holding a substrate in a curved state”

can be understood as a holder which is configured for holding a substrate as described herein, particularly a large area substrate as described herein, in a curved or bent state. Typically, the substrate held or supported by the carrier as described herein includes a front surface 10F and a back surface 10B, as exemplarily indicated in FIG. 1. The front surface is the surface of the substrate on which a layer is to be deposited. The back surface of the substrate is the surface of the substrate facing the carrier body. In particular, the carrier for holding the substrate is configured for substantially vertically holding the substrate. In the present disclosure, the term “substantially vertical” can be understood as vertical within a tolerance T of T≤±15°, particularly T≤±10°, more particularly T≤±5°, for instance T≤±1°, from the absolute vertical direction. The absolute vertical direction corresponds to the direction of gravity.

In the present disclosure, a “substrate in a curved state” can be understood as a substrate which is bent about a bending axis. Accordingly, it is to be understood that initially the substrate is substantially flat and when the substrate is fixed to the carrier, the substrate is bent and has a curved state. Accordingly, in the curved or bent state of the substrate (i.e. when the substrate being fixed to the carrier) mechanical tensions occur in the substrate. Further, it is to be understood that typically when the substrate is demounted or released from the carrier the substrate goes back into the initial substantially flat state. Accordingly, typically the substrate is elastic.

The radius of curvature of the substrate in the curved or bent state can be constant or non-constant. Typically, the bending axis is substantially vertical. In the exemplary embodiments shown in the figures, the substrate is bent about a vertical bending axis. Alternatively, the bending axis can be substantially horizontal (not explicitly shown in the figures). In the present disclosure, the term “substantially horizontal” can be understood as horizontal within a tolerance T of T≤±15°, particularly T≤±10°, more particularly T≤±5°, for instance T≤±1°, from the absolute horizontal direction. The absolute horizontal direction is perpendicular to the absolute vertical direction.

In the present disclosure, the term “substrate” may particularly embrace substantially inflexible substrates, e.g., glass plates or metal plates. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates. Typically, the substrate as described herein is an elastic substrate. Further, it is to be understood that a substrate as described herein can be bent into a curved state. Accordingly, an initially flat or plate-like substrate can be fixed to a carrier body having a curved substrate support surface as described herein such that the substrate is held in a curved or bent state. For example, the substrate can have a thickness of 0.1 mm to 1.8 mm. According to embodiments described herein, the substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

According to some embodiments, the substrate can be a “large area substrate” and may be used for display manufacturing. For instance, the substrate may be a glass or plastic substrate. For example, substrates as described herein shall embrace substrates which are typically used for an LCD (Liquid Crystal Display), a PDP (Plasma Display Panel), and the like. For instance, a “large area substrate” can have a main surface with an area of 0.5 m² or larger, particularly of 1 m² or larger. In some embodiments, a large area substrate can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

In the present disclosure, a “carrier body” can be understood as a rigid body of the carrier which is configured for supporting the substrate. Typically, the carrier body has a curved substrate support surface. A “substrate support surface” can be understood as a surface of the carrier facing the substrate, particularly the back side of the substrate. For instance, the curved substrate support surface can be convex or concave. The curved substrate support surface can include a constant or non-constant radius of curvature. Typically, the curved substrate support surface is purely convex or purely concave. In other words, the curved substrate support surface may only be convex with a constant or non-constant radius of curvature. Alternatively, the curved substrate support surface may only be concave with a constant or non-constant radius of curvature. It is to be understood that when a gas cushion is provided between a back side 10B of the substrate 10 and the curved substrate support surface 111, there is no contact between the curved substrate support surface 111 and the back side 10B of the substrate 10. In other words, in an operation state in which a gas cushion is provided, the substrate can be held contact-free with respect to the substrate support surface 111.

In the present disclosure, a “sealing” can be understood as sealing configured for providing an air tight sealing between an edge of the substrate and the carrier body as described herein, such that a gas cushion between the back side of the substrate and the substrate support surface can be provided. Typically, the sealing is configured to provide a line contact, particularly a closed-lined contact, between the back side of the substrate and the sealing. Accordingly, typically the sealing is configured to provide a line contact, particularly a closed-lined contact, between the sealing and the front side of the carrier body, particularly the curved substrate support surface.

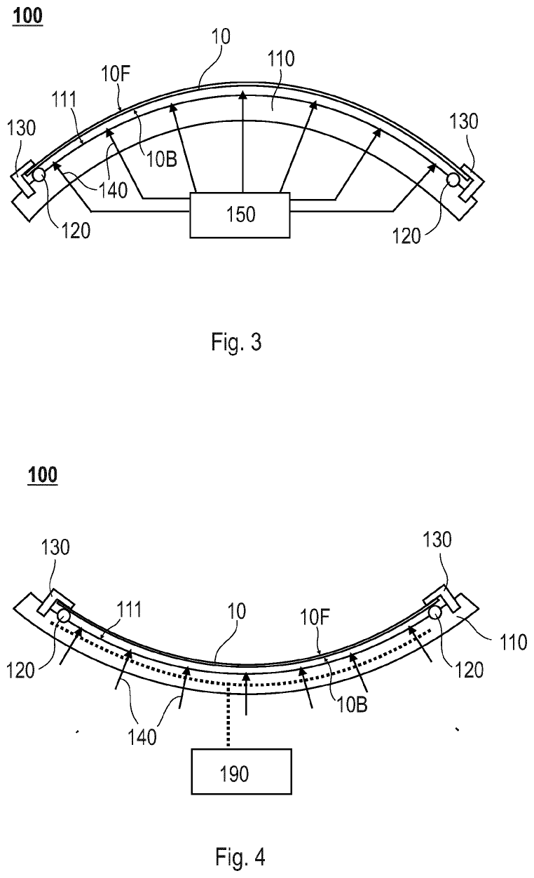

In the present disclosure, an “edge of the substrate” can be understood as an edge of the front surface of the substrate, particularly an edge region of the front surface of the substrate. In particular, the “edge of the substrate” can be understood as the complete edge of the substrate. In other words, the term “edge of the substrate” may include all edges on all sides of the substrate. More specifically, in the case of a vertically held substrate, as exemplarily shown in FIG. 2, the term “edge of the substrate” may include the upper edge 10UE, the bottom edge 10BE and the lateral edges 10LE between the upper edge 10UE and the bottom edge 10BE of the substrate 10, as exemplarily indicated in FIG. 2.

In the present disclosure, a “substrate fixation” can be understood as a fixation configured for fixing the substrate to the carrier, particularly to the carrier body. Typically, the substrate fixation is configured for pressing the edge of the substrate onto the sealing as described herein. In other words, the substrate fixation can be configured to exert a compression force onto the edge of the substrate. Further, it is to be understood that typically the substrate fixation is configured to hold the substrate in a curved state as described. In other words, typically the substrate fixation is configured to counteract the reaction forces, such as substrate tensions and substrate stresses, occurring when the substrate is fixed to the carrier body in a curved or bent state as described herein.

In the present disclosure, the expression that the “carrier body comprises one or more gas supply conduits to provide a gas cushion between a back side of the substrate and the substrate support surface” can be understood in that at least one gas supply conduit is provided in the carrier body through which gas can be supplied into a space between the back side of the substrate and the substrate support surface, such that a gas cushion can be provided. In FIG. 1, the one or more gas supply conduits 140 are schematically indicated by arrows. Typically, the gas supply conduits include gas outlet openings provided in the substrate support surface of the carrier body.

In the present disclosure, a “gas cushion” can be understood as a volume filled with gas, particularly of constant pressure. In particular, in embodiments described herein, the gas filled volume, i.e. the gas cushion, is provided between the back side 10B of the substrate 10 and the substrate support surface 111, wherein the back side of the substrate is sealed against the substrate support surface via the sealing 120 as described herein.

According to embodiments, which can be combined with any other embodiments described herein, the substrate fixation 130 may include a plurality of clamps. As exemplarily shown in FIG. 2, the substrate fixation 130, particularly the plurality of clamps, may be distributed over the edge of the carrier and configured to press the edge of the substrate 10 onto the sealing 120. It is to be understood that typically the substrate fixation 130, particularly the plurality of clamps, are connected with the carrier body 110.

According to embodiments, which can be combined with any other embodiments described herein, the sealing 120 is made of a flexible material. In particular, the sealing 120 can be made of a flexible polymeric material. Accordingly, when the edge of the substrate is pressed onto the sealing 120 by the substrate fixation 130, an air-tight sealing can be provided.

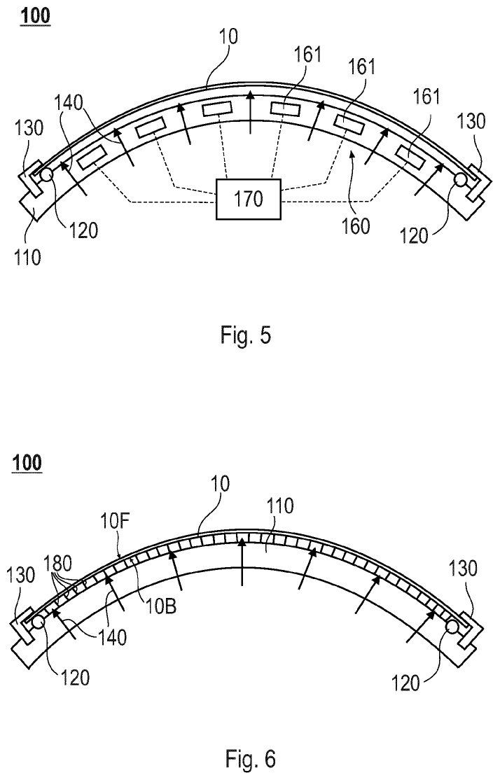

According to embodiments, which can be combined with any other embodiments described herein, the carrier includes a gas supply 150 connected to the one or more gas supply conduits 140 to provide the gas cushion, as schematically shown in FIG. 3. For instance, the gas supply may include a gas tank, which can be part of a deposition system as described herein. The gas supply 150 can be configured to provide a gas cushion pressure p of up to 1 bar, particularly the gas cushion pressure p may be 1 Pa≤p≤1 bar, more particularly 5 Pa≤p≤1 bar. According to an example, the gas cushion pressure p may be 1 Pa≤p≤50 Pa, particularly 1 Pa≤p≤20 Pa. Further, the gas supply can be configured to supply an inert gas, e.g. argon, helium or other inert gases.

According to embodiments, which can be combined with any other embodiments described herein, the curved substrate support surface 111 is convex for holding a convex substrate, as exemplarily shown in FIG. 1. A convex substrate support surface can beneficially provide for good self-aligning of the convex substrate to the convex substrate support surface. The term “self-aligning” can be understood in that the substrate aligns substantially parallel to the substrate support surface due to the substrate tension in the curved or bent state of the substrate.

Alternatively, the curved substrate support surface 111 can be concave for holding a concave substrate, as exemplarily shown in FIG. 4, which may also provide for improved substrate self-aligning as compared to the state of the art. Further, as compared to a convex substrate support surface, a concave substrate support surface can be beneficial for reducing the risk of substrate lift-off. Additionally, as compared to a convex substrate support surface, the substrate fixation, particularly the pressing of the substrate onto the sealing may be simpler. In other words, in a concave configuration, the compression force for providing an air-tight sealing between the substrate and the sealing can be less as compared to a convex configuration.

With exemplary reference to FIG. 4, according to embodiments which can be combined with any other embodiments described herein, the carrier 100 may include a cooling system 190 for cooling the carrier body 110. Although the cooling system 190 system in shown in combination with the concave configuration in FIG. 4, it is to be understood that the cooling system 190 can be provided in any embodiments described herein. For instance, the cooling system 190 can include a coolant supply for providing a coolant. For example, the cooling system 190 may be a closed-loop cooling system, particularly a closed-loop refrigerating system. Typically, the cooling system includes a piping for the coolant. The piping can be embedded in the carrier body. Additionally or alternatively, the piping can be provided on the backside of the carrier body. The coolant can be understood as a cooling fluid, particularly an incompressible cooling fluid, enabling to provide a cooling of the substrate such that the substrate temperature is provided to be at 100° C. or below, particularly 80° C. or below. For example, the coolant can be water or oil. Accordingly, according to embodiments which can be combined with any other embodiments described herein, the carrier body can be a cooled carrier body, e.g. an oil-cooled or water-cooled carrier body.

With exemplary reference to FIG. 5, according to embodiments which can be combined with any other embodiments described herein, the carrier further includes an electrostatic chuck 160 for holding the substrate via electrostatic force. In particular, the electrostatic chuck 160 may include an electrode assembly having a plurality of electrodes 161 for providing electrostatic forces to the substrate. Typically, the electrode assembly is embedded in the carrier body 110. Accordingly, it is to be understood that an electrostatic field may be provided by the electrode assembly to act on the substrate for holding the substrate.

According to some embodiments, which can be combined with other embodiments described herein, the electrostatic chuck 160 may include one or more voltage sources (not explicitly shown) configured to apply one or more voltages to the plurality of electrodes 161. In some implementations, the one or more voltage sources are configured to ground at least some electrodes of the plurality of electrodes. As an example, the one or more voltage sources can be configured to apply a first voltage having a first polarity, a second voltage having a second polarity, and/or ground to the plurality of electrodes. According to some embodiments, each electrode, every second electrode, every third electrode or every fourth electrode of the plurality of electrodes can be connected to a separate voltage source. The term “polarity” refers to an electric polarity, i.e., negative (−) and positive (+). As an example, the first polarity can be the negative polarity and the second polarity can be the positive polarity, or the first polarity can be the positive polarity and the second polarity can be the negative polarity. According to some embodiments, which can be combined with other embodiments described here, the electrostatic chuck 160 of the substrate support can be a mono-polar or a bi-polar electrostatic chuck.

With exemplary reference to FIG. 5, according to some embodiments which can be combined with other embodiments described herein, a controller 170 may be provided which can be configured to control the one or more voltage sources for applying the one or more voltages and/or ground to the plurality of electrodes 161. The controller 170 may be configured to regulate the electrostatic chuck, i.e. the controller may be configured to control the electrostatic chucking. Although not explicitly shown, it is to be understood that the controller 170 may be configured to regulate the gas supply 150. The controller 170 may be separated into individual controllers, i.e. a controller for the electrostatic chuck and a separate controller for the gas supply. It is to be understood that, in the case that no electrostatic chuck is provided, only the controller for controlling the gas supply may be provided.

Typically, a controller as described herein comprises a central processing unit (CPU), a memory and, for example, support circuits. The CPU may be one of any form of general-purpose computer processor that can be used in an industrial setting for controlling various chambers and sub-processors. The memory is coupled to the CPU. The memory, or a computer readable medium, may be one or more readily available memory devices such as random-access memory, read only memory, hard disk, or any other form of digital storage either local or remote. The support circuits may be coupled to the CPU for supporting the processor in a conventional manner. The support circuits typically include cache, power supplies, clock circuits, input/output circuitry and related subsystems, and the like. Controlling instructions are generally stored in the memory as a software routine typically known as a recipe. The software routine may also be stored and/or executed by a second CPU that is remotely located from the hardware being controlled by the CPU.

With exemplary reference to FIG. 6, according to embodiments which can be combined with any other embodiments described herein, the curved substrate support surface 111 comprises a plurality of filaments 180 of dry adhesive material for attaching a back side 10B of the substrate 10. For illustration purposes only, some filaments are marked by reference numbers. Typically, the plurality of filaments 180 are attached to the curved substrate support surface 111 and extend away from curved substrate support surface 111. Accordingly, it is to be understood that typically the plurality of filaments 180 have a free end to attach a substrate as described herein. More specifically, the free ends of the plurality of filaments are typically configured to adhere to the substrate by van der Waals forces. Accordingly, it is to be understood that the plurality of filaments 180 may provide for an adhesive arrangement which provides for a permeable or porous configuration of the adhesive arrangement. In other words, the structure of the adhesive arrangement can be configured to be porous or spongy in a way that the gas can reach the back side 10B of the substrate 10.

According to an example, the dry adhesive material can be a synthetic setae material. In particular, the dry adhesive material can be a Gecko adhesive. Typically, the dry adhesive material is configured for providing the adhesive force by van der Waals forces. For instance, the filaments can be nanotubes or carbon nanotubes.

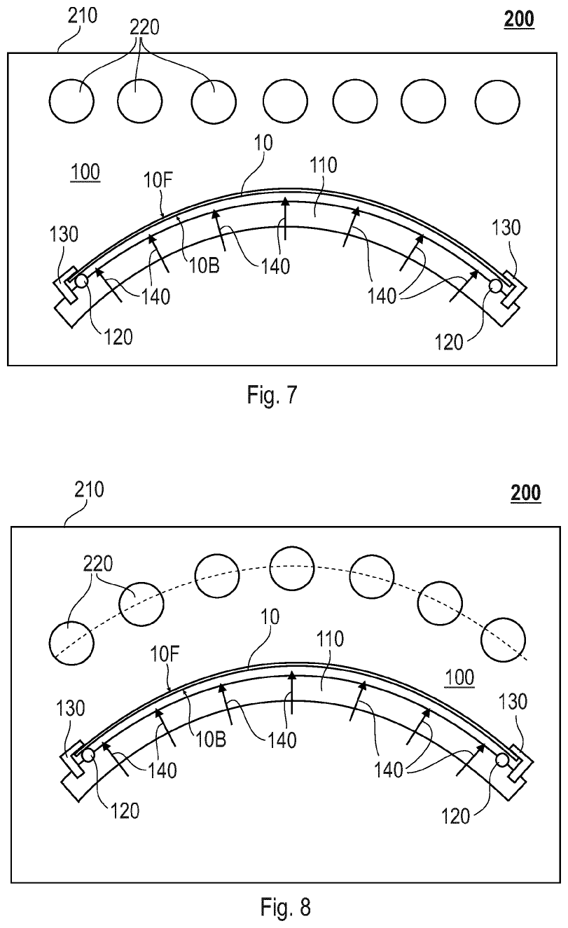

With exemplary reference to FIG. 7, an apparatus 200 for depositing a layer on a substrate 10 in a curved state according to the present disclosure is described. According to embodiments, which can be combined with any other embodiments described herein, the apparatus 200 includes a vacuum deposition chamber 210, an arrangement of deposition sources 220, and a carrier 100 according to any embodiments described herein. In particular, the arrangement of deposition sources 220 and the carrier 100 for holding the substrate 10 are arranged within the vacuum deposition chamber 210.

In the present disclosure, the term “vacuum” can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar.

In the present disclosure, an “arrangement of deposition sources” can be understood as an arrangement of a plurality of deposition sources. The individual deposition sources of the arrangement of deposition sources may be of identical or different configuration.

In the present disclosure, a “deposition source” can be understood as a source configured for material deposition, particularly by employing a sputter deposition process, particularly a magnetron sputtering process. Typically, the deposition source is a vertical deposition source, i.e. having a longitudinal main axis extending in a substantially vertical direction. It is to be understood that for depositing a layer on the substrate, the carrier with the substrate can be continuously moved during deposition past the deposition sources (“dynamic coating”). Alternatively, the carrier with the substrate may rest essentially at a constant position during layer deposition (“static coating”). Further, also substrate sweeping or substrate wobbling may be possible. The embodiments described in the present disclosure relate to both dynamic coating and static coating processes. For the example for moving the carrier, a transportation system, particularly including a magnetic levitation system, can be employed. Typically, the magnetic levitation system is configured to levitate or hold the carrier without mechanical contact or with reduced mechanical contact by magnetic forces. Further, the magnetic levitation system can be configured to move the carrier by magnetic forces.

According to some embodiments described herein, which can be combined with other embodiments described herein, the deposition material of the deposition sources can be chosen according to the deposition process and the later application of the coated substrate. For instance, the deposition material can be a material selected from the group consisting of: metals, such as aluminum, molybdenum, titanium, copper, or the like, silicon, indium tin oxide, and other transparent conductive oxides. Oxide-, nitride- or carbide-layers, which can include such materials, can be deposited by providing the material from the material deposition source or by reactive deposition, i.e. the material from the material deposition source can react with elements like oxygen, nitride, or carbon from a processing gas.

According to some embodiments, which can be combined with any other embodiments described herein, the arrangement of deposition sources 220 follows the curvature of the substrate, as exemplarily shown in FIG. 8. In other words, the deposition sources 220 may be substantially parallel with respect to the front surface 10F of the substrate.

With exemplary reference to the block diagram shown in FIG. 7, a method 300 for supporting a substrate in a curved state according to the present disclosure is described. According to embodiments, which can be combined with any other embodiments described herein, the method 300 includes providing (represented by block 310) a carrier 100 for supporting the substrate 10 according to any embodiments described herein. Further, the method includes providing (represented by block 320) a gas cushion between a back side 10B of the substrate 10 and the curved substrate support surface 111. Typically, providing the gas cushion comprises introducing gas through one or more gas supply conduits 140 by using a gas supply 150. In particular, the gas cushion is provided at a pressure p of 1 Pa≤p≤20 Pa.

In view of the embodiments described herein, it is to be understood that, compared to the state of the art, improved carriers, apparatuses and methods for substrates are provided. In particular, by providing a carrier which is configured to hold a substrate in a curved or bent state, the holding stability of the substrate can be improved due to mechanical tensions in the substrate caused by the curved or bent state. Further, embodiments described herein beneficially provide for improved thermal conductance performance from the substrate to the carrier, such that cooling efficiency of the substrate can be improved. Further, it is to be noted that embodiments described herein particular beneficially provide for a reduction of possible substrate damage. Additionally, the alignment of the substrate with respect to the susceptor, i.e. the carrier can be improved such that the overall layer deposition quality is improved.

While the foregoing is directed to embodiments of the disclosure, other and further embodiments of the disclosure may be devised without departing from the basic scope thereof, and the scope thereof is determined by the claims that follow.

1. A carrier for holding a substrate in a curved state, comprising:
a carrier body having a curved substrate support surface,
a sealing for providing a sealing between an edge of the substrate and the carrier body, and
a substrate fixation for pressing the edge of the substrate onto the sealing, wherein the carrier body comprises one or more gas supply conduits to provide a gas cushion between a back side of the substrate and the curved substrate support surface.

2. The carrier according to claim 1, wherein the substrate fixation comprises a plurality of clamps.

3. The carrier according to claim 1, wherein the sealing is made of a flexible material.

4. The carrier according to claim 1, further comprising a gas supply connected to the one or more gas supply conduits to establish the gas cushion.

5. The carrier according to claim 4, wherein the gas supply is configured to provide a gas cushion pressure p of 1 Pa≤p≤20 Pa.

6. The carrier according to claim 1, wherein the curved substrate support surface is convex for holding the substrate in a convex state.

7. The carrier according to claim 1, wherein the curved substrate support surface is concave for holding the substrate in a concave state.

8. The carrier according to claim 1, further comprising a cooling system for cooling the carrier body.

9. The carrier according to claim 1, further comprising an electrostatic chuck for holding the substrate via electrostatic force.

10. The carrier according to claim 1, wherein the curved substrate support surface comprises a plurality of filaments of dry adhesive material for attaching a back side of the substrate, the plurality of filaments extending away from the curved substrate support surface.

11. The carrier according to claim 10, wherein the dry adhesive material is a synthetic setae material.

12. An apparatus for depositing a layer on a substrate in a curved state, comprising:
a vacuum deposition chamber,
an arrangement of deposition sources, and
a carrier for holding the substrate in a curved state, the carrier comprising:
a carrier body having a curved substrate support surface,
a sealing for providing a sealing between an edge of the substrate and the carrier body, and
a substrate fixation for pressing the edge of the substrate onto the sealing, wherein the carrier body comprises one or more gas supply conduits to provide a gas cushion between a back side of the substrate and the curved substrate support surface.

13. The apparatus of claim 16, wherein the arrangement of deposition sources follows the curvature of the substrate.

14. A method for supporting a substrate in a curved state in a vacuum deposition chamber, the method comprising:
providing a carrier for supporting the substrate in the curved state, the carrier comprising:
a carrier body having a curved substrate support surface,
a sealing for providing a sealing between an edge of the substrate and the carrier body, and
a substrate fixation for pressing the edge of the substrate onto the sealing, wherein the carrier body comprises one or more gas supply conduits to provide a gas cushion between a back side of the substrate and the curved substrate support surface, and
providing a gas cushion between a back side of the substrate and the curved substrate support surface.

15. The method of claim 18, wherein providing the gas cushion comprises introducing gas through one or more gas supply conduits by using a gas supply.

16. The method of claim 18, wherein the gas cushion is provided at a pressure p of 1 Pa≤p≤20 Pa.

17. The carrier according to claim 1, wherein the substrate is a plate substrate of elastic material.

18. The carrier according to claim 1, wherein the sealing is configured for providing an air tight sealing between the edge of the substrate and the carrier body.

19. The carrier according to claim 1, wherein the substrate fixation is configured to exert a compression force onto the edge of the substrate.

20. The carrier according to claim 1, wherein the gas cushion is a volume filled with gas of constant pressure.
